(19) United States
(12) Patent Application Publication
(10) Pub. No.: US 2012/0033353 A1
(43) Pub. Date: Feb. 9, 2012

(54) FOLDABLE ELECTRONIC DEVICE

(75) Inventor: Yi Di Huang, Taipei County (TW)

(73) Assignee: MICRO-STAR INTERNATIONAL CORPORATION LIMITED, Taipei County (TW)

(21) Appl. No.: 12/887,244

(22) Filed: Sep. 21, 2010

(30) Foreign Application Priority Data
Aug. 4, 2010 (TW) 099214926

(51) Int. Cl. H05K 7/00

(52) U.S. Cl. 361/679.01

(57) ABSTRACT

A foldable electronic device includes a foldable casing, a flexible electronic element, and at least one roller. The flexible electronic element is disposed in the foldable casing, and the roller is correspondingly pivoted to a bending position of the foldable casing. The roller enables the flexible electronic element to slide and to be bent along the roller when being unfolded or folded together with the foldable casing, so as to avoid the generation of creases, such that the flexible electronic element is capable of serving as a display screen of the foldable electronic device.

### CROSS-REFERENCE TO RELATED APPLICATIONS

This non-provisional application claims priority under 35 U.S.C. §119(a) on Patent Application No(s). 099214926 filed in Taiwan, R.O.C. on Aug. 4, 2010, the entire contents of which are hereby incorporated by reference.

### BACKGROUND OF THE INVENTION

1. Field of Invention

The present invention relates to a foldable electronic device, and more particularly to a foldable electronic device with a flexible display as a display screen.

2. Related Art

In recent years, with the rapid development of technology and information, manufacturing technologies of electronic products are also improved gradually. In consideration of the pursuit of portability and practicability, the electronic products develop towards being light, thin, short, and small. For example, screens have developed from early large-volume and large-weight cathode ray tube (CRT) displays to light-weight and thin-volume liquid crystal display (LCD) displays. Moreover, due to the pursuit of small size of electronic products for convenient carrying, the size of displays gets smaller relatively. However, common displays generally cannot have convenience in carrying and comfort in use at the same time, that is, when the screen gets smaller and can be easily carried, the area of the screen is reduced correspondingly, such that the content of the screen frame is reduced, and is inconvenient for the user for watching. In order to solve this problem, foldable electronic screens are developed, that is, a plurality of small-size displays are combined into a large-size screen, but joints are generated between the displays, and thus the frame quality is deteriorated.

Therefore, current flexible displays, for example, electronic paper or organic light-emitting diodes (OLED) displays, have been developed, and are available in the market. Presently, the flexible displays applied on electronic devices for the purpose of reducing the volume are in the manner of rolling. The flexible displays in the manner of rolling can overcome the disadvantage of deteriorated frame quality caused by combining a plurality of small-size displays into a large-size screen. However, the flexible display has a requirement of minimal bending curvature when being rolled up, and due to excessive small curvature, the flexible display has a fold, and cannot display normally when being unfolded again, so the flexible screen cannot be rolled up to be excessively small. Therefore, the conventional design cannot solve the problem, and the flexible display cannot be implemented on the current foldable electronic products.

### SUMMARY OF THE INVENTION

Accordingly, the present invention is a foldable electronic device, so as to solve the problem of generation of creases when a flexible screen is applied in a foldable electronic device existing in the prior art.

The present invention provides a foldable electronic device, which comprises a foldable casing, a flexible electronic element, and at least one roller. The foldable casing is capable of being unfolded or folded, the flexible electronic element is disposed in the foldable casing, and the flexible screen and the foldable casing are unfolded or folded together. Furthermore, the roller is correspondingly pivoted to a bending position of the foldable casing, such that the flexible electronic element slides and is bent along the roller when being folded.

In the foldable electronic device of the present invention, the foldable casing has at least two casing bodies pivoted to each other and capable of being unfolded and folded with respect to each other. When the two casing bodies are unfolded with respect to each other, a bearing range is formed thereby, and the flexible electronic element is disposed on the bearing range.

In the foldable electronic device of the present invention, the two casing bodies are pivoted to each other through at least one pivot, the roller is pivoted to the pivot and is normally pressed against the flexible electronic element, such that the flexible electronic element slides and is bent along the roller when being folded.

In the foldable electronic device of the present invention, the foldable casing has three casing bodies pivoted to each other through at least two pivots and capable of unfolded and folded with respect to each other. When the three casing bodies are unfolded with respect to each other, a bearing range is formed thereby, and the flexible electronic element is disposed on the bearing range.

In the foldable electronic device of the present invention, the foldable electronic device comprises two rollers, and three casing bodies are pivoted to each other through at least two pivots, and two rollers are respectively pivoted to the two pivots and are normally pressed against the flexible electronic element, such that the flexible electronic element slides and is bent along the rollers.

In the foldable electronic device of the present invention, one of the two rollers has an outer diameter greater than that of the other one.

In the foldable electronic device according to the present invention, the flexible screen is capable of being unfolded or folded together with the foldable casing. However, when the flexible screen is bent, creases may be generated. Therefore, the foldable electronic device of the present invention has a roller, and the roller is disposed on a bearing to which the foldable casing is pivoted and is pressed against the flexible screen, and has a radius greater than the flexible radius of the flexible screen, such that the flexible screen is capable of being bent along the outer diameter of the roller and extending and sliding, thus no crease is generated on the flexible screen and no frictions and damages on the foldable casing occur. Therefore, the present invention solves the problems and applies the flexible display in the foldable electronic device to achieve the efficacy of having a minimal volume when being folded and having a maximal display screen when being unfolded.

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

The accompanying drawings illustrate one or more embodiments of the invention and, together with the written description, serve to explain the principles of the invention. Wherever possible, the same reference numbers are used throughout the drawings to refer to the same or like elements of an embodiment, and wherein:

FIG. 1A is a schematic view of a foldable electronic device according to an embodiment of the present invention;

FIG. 1B is a schematic structural view of a foldable electronic device according to an embodiment of the present invention;

FIG. 2A is a plane cross-sectional view of the foldable electronic device in FIG. 1;

FIG. 2B is a schematic view of a first casing body in FIG. 2A folded to a second casing body;

FIG. 2C is a schematic view of a third casing body in FIG. 2B folded to the first casing body; and

FIG. 3 is a schematic structural view of a foldable electronic device according to another embodiment of the present invention.

### DETAILED DESCRIPTION OF THE INVENTION

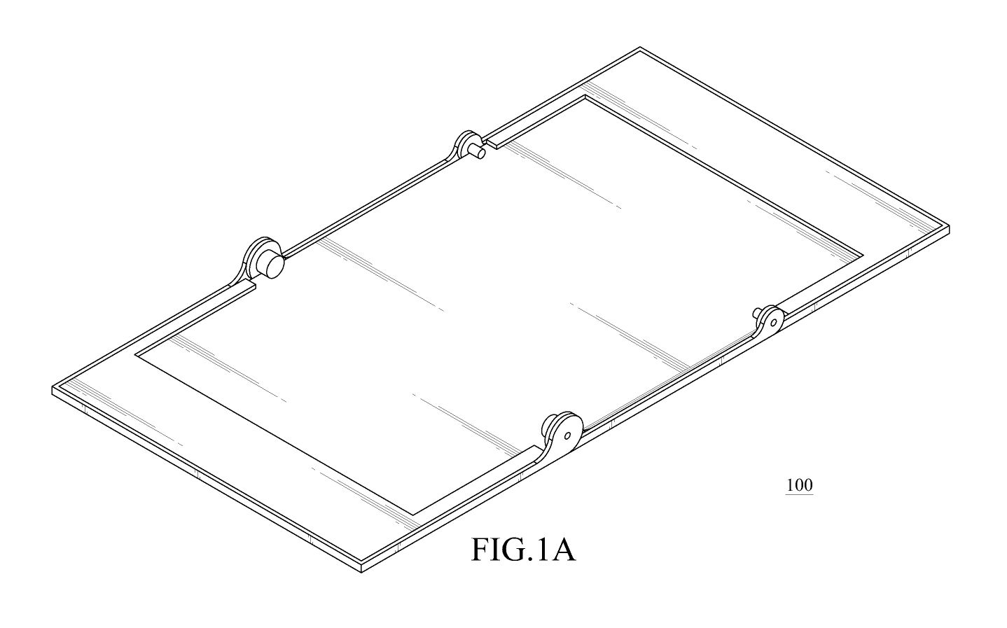

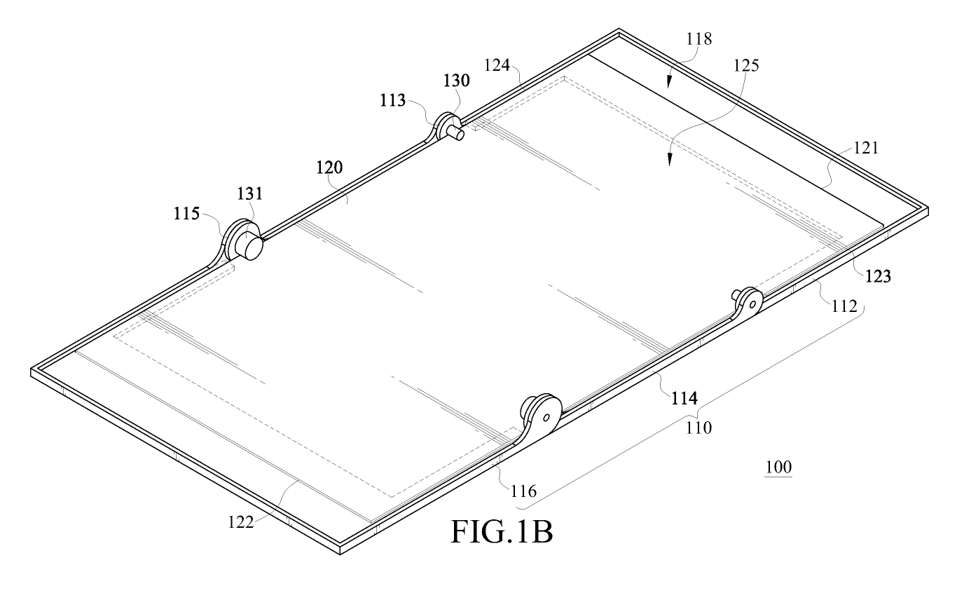

FIG. 1A is a schematic view of a foldable electronic device according to an embodiment of the present invention, and FIG. 1B is a schematic structural view of a foldable electronic device according to an embodiment of the present invention. Referring to FIGS. 1A and 1B, a foldable electronic device 100 of this embodiment is a two-folded foldable electronic device, and comprises a foldable casing 110, a flexible screen 120, two first rollers 130, and two second rollers 131. The foldable casing 110 comprises a first casing body 112, a second casing body 114, a third casing body 116, two first pivots 113, and two second pivots 115. The first pivot 113 connects the first casing body 112 and the second casing body 114, such that the first casing body 112 and the second casing body 114 are pivoted to each other, and capable of being unfolded or folded with respect to each other. The second pivot 115 connects the second casing body 114 and the third casing body 116, such that the second casing body 114 and the third casing body 116 are pivoted to each other, and capable of being unfolded or folded with respect to each other. Therefore, the foldable casing 110 enables the first casing body 112, the second casing body 114, and the third casing body 116 to be unfolded and folded with respect to each other through the arrangement of the first pivot 113 and the second pivot 115. Furthermore, when the first casing body 112, the second casing body 114, and the third casing body 116 are unfolded with respect to each other to be a maximal plane, a bearing range 118 is formed thereby. Additionally, the first roller 130 is pivoted to the first pivot 113, and is capable of rotating with respect to the first pivot 113, and the second roller 131 is pivoted to the second pivot 115, and is capable of rotating with respect to the second pivot 115. The roller radius of the first roller 130 and the second roller 131 needs to be greater than the flexible radius of the flexible screen 120, and the roller radius of the second roller 131 needs to be greater than that of the first roller 130.

The flexible screen 120 of the present invention is disposed on the bearing range 118 and has a shape of rectangular plate, but is not limited thereto. The flexible screen 120 has a first edge 121, a second edge 122 opposite to the first edge 121, a third edge 123, and a fourth edge 124 opposite to the third edge 123. The first edge 121 is connected to the first casing body 112, and the second edge 122 is connected to the third casing body 116. The third edge 123 and the fourth edge 124 are adjacent to the first pivot 113 and the second pivot 115 simultaneously, but not connected to the first casing body 112, the second casing body 114, or the third casing body 116. Therefore, only the first edge 121 and the second edge 122 of the flexible screen 120 are constrained in the foldable casing 110, that is, the flexible screen 120 is disposed on the bearing range 118 in a floating manner. Furthermore, the flexible screen 120 further has a display surface 125, in which the first edge 121, the second edge 122, the third edge 123, and the fourth edge 124 surround the display surface 125, and the display surface 125 is disposed with its back facing the foldable casing 110. The display surface 125 is pressed against the first roller 130 and the second roller 131. The flexible screen 120 is capable of being unfolded or folded together with the foldable casing 110, the flexible screen 120 is bent and slides along an outer edge of the first roller 130 or the second roller 131 by taking the axis of the first pivot 113 or the second pivot 115 as the center of circle, and drives the first roller 130 or the second roller 131 to rotate together.

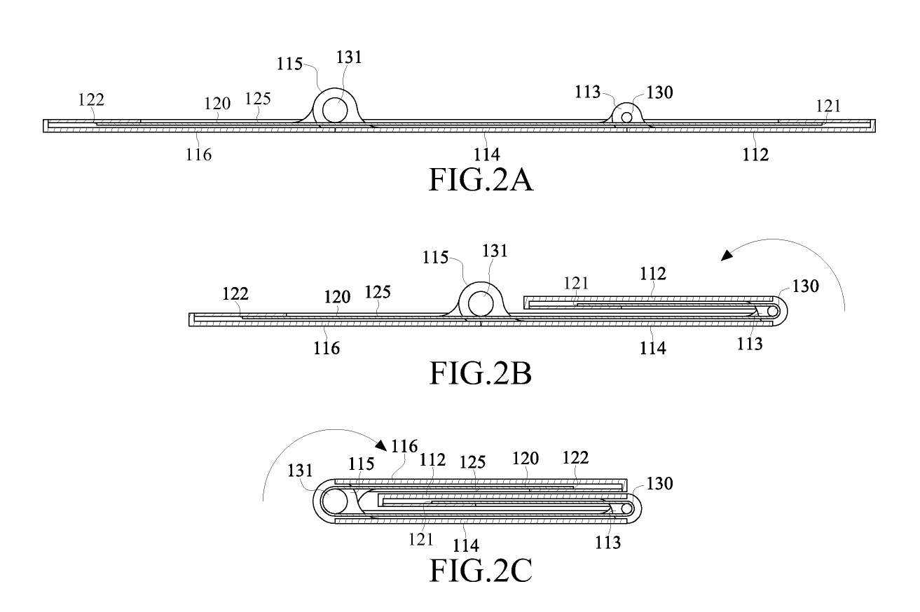

The folding manner of the foldable electronic device 100 is described in detail below. FIG. 2A is a plane cross-sectional view of the foldable electronic device in FIG. 1, FIG. 2B is a schematic view of a first casing body of FIG. 2A folded to a second casing body, and FIG. 2C is a schematic view of a third casing body in FIG. 2B folded to the first casing body. The display surface 125 of the flexible screen 120 is pressed against the first roller 130 and the second roller 131, the first edge 121 is fixed to the first casing body 112, and the second edge 122 is fixed to the third casing body 116. Next, the first casing body 112 performs a counter-clockwise circular motion with respect to the second casing body 114 and rotates for 180 degrees by taking the axis of the first pivot 113 as the center of circle, and then is folded to the second casing body 114, as shown in FIG. 2B. At this time, the first edge 121 of the flexible screen 120 is fixed to the first casing body 112, and the flexible screen 120 is pressed against the first roller 130 of the first pivot 113, such that the flexible screen 120 is driven by the first casing body 112 to slide and to be bent along the first roller 130, and the first roller 130 rotates together due to the bending of the flexible screen 120. Next, the third casing body 116 performs a clockwise circular motion with respect to the second casing body 114 and rotates for 180 degrees by taking the axis of the second pivot 115 as the center of circle, and then is folded to the first casing body 112, as shown in FIG. 2C. At this time, the second edge 122 of the flexible screen 120 is fixed to the third casing body 116, and the flexible screen 120 is pressed against the second roller 131 on the second pivot 115, such that the flexible screen 120 is driven by the third casing body 116 to slide and to be bend along the second roller 131, and the second roller 131 rotates together due to the bending of the flexible screen 120.

At this time, the foldable casing 110 is changed from an unfolded state into a folded state, and the occupied space is reduced, thus being convenient for a user to carry. In order to get an intact appearance and uniform thickness of the foldable casing 110 after being folded and get a plane without height difference of the flexible screen 120 after being unfolded, the first roller 130 and the second roller 131 must have different roller radiuses. As for the present invention, the first roller 130 has a roller radius lower than that of the second roller 131. Furthermore, the casing body thickness of the first casing body 112, the second casing body 114, and the third casing body 116, the pivot radius of the first pivot 113 and the second pivot 115, and the roller radius of the first roller 130 and the second roller 131 need to meet the following relationships:

(Casing body thickness of the second casing body 114)+(Casing body thickness of the third casing body 116)<(Pivot radius of the second pivot 115);

(Casing body thickness of the first casing body 112)>(Pivot radius of the second pivot 115)−(Roller radius of the second roller 131);

(Casing body thickness of the third casing body 116)>(Pivot radius of the first pivot 113)−(Roller radius of the first roller 130).

As the foldable casing 110 has the first roller 130 and the second roller 131 disposed therein, and the roller radius of the first roller 130 and the second roller 131 is greater than the flexible radius of the flexible screen 120, when the flexible screen 120 is bent along the first roller 130 or the second roller 131, no crease is generated. Furthermore, as the flexible screen 120 is pressed against the first roller 130 and the second roller 131 when being bent, such that the first roller 130 and the second roller 131 rotates together when the flexible screen 120 is bent, and no friction and damage is generated between the flexible screen 120 and the foldable casing 110.

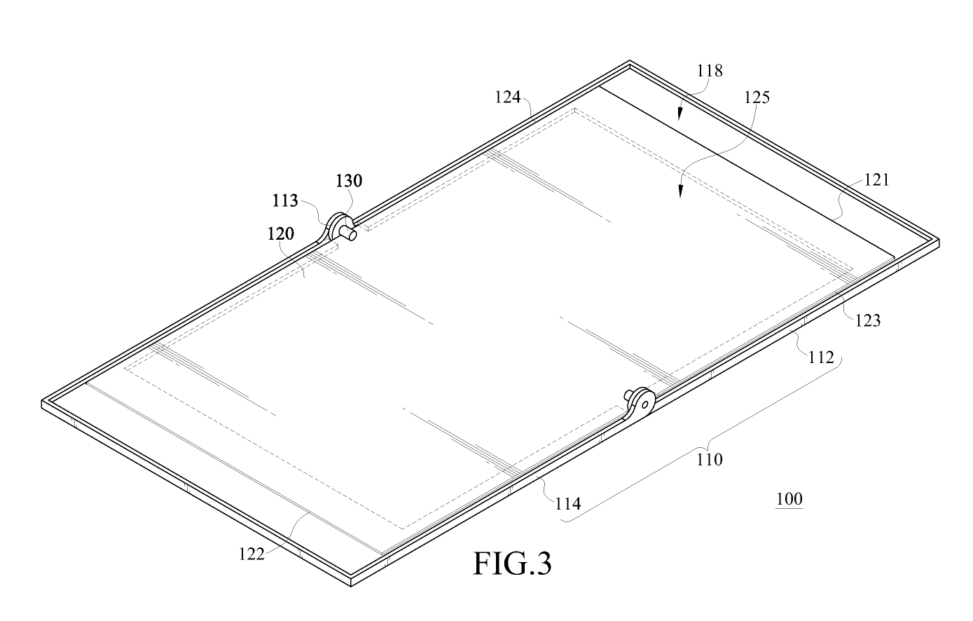

FIG. 3 is a schematic structural view of a foldable electronic device according to another embodiment of the present invention. As the structure of this embodiment is substantially the same as that of the embodiment in FIG. 1, only differences therebetween are described herein. A foldable electronic device 100 comprises a foldable casing 110, a flexible screen 120, and two first rollers 130. The foldable casing 110 comprises a first casing body 112, a second casing body 114, and two first pivots 113. The first pivot 113 connects the first casing body 112 and the second casing body 114, such that the first casing body 112 and the second casing body 114 are pivoted to each other, and are capable of being unfolded or folded with respect to each other. Therefore, the foldable casing 110 enables the first casing body 112 and the second casing body 114 to be unfolded and folded with respect to each other through the arrangement of the first pivot 113. Moreover, when the first casing body 112 and the second casing body 114 are unfolded with respect to each other to a maximal plane, a bearing range 118 is formed thereby. Furthermore, the first roller 130 is pivoted to the first pivot 113, and is capable of rotating with respect to the first pivot 113, and the roller radius of the first roller 130 needs to be greater than the flexible radius of the flexible screen 120. The flexible screen 120 is disposed on the bearing range 118, and has a first edge 121, a second edge 122 opposite to the first edge 121, a third edge 123, and a fourth edge 124 opposite to the third edge 123. The first edge 121 is connected to the first casing body 112, and the second edge 122 is connected to the second casing body 114. Furthermore, the flexible screen 120 has a display surface 125, in which the first edge 121, the second edge 122, the third edge 123, and the fourth edge 124 surrounds the display surface 125, and the display surface 125 is disposed with its back facing the foldable casing 110, and is pressed against the first roller 130. The flexible screen 120 is capable of being unfolded or folded together with the foldable casing 110, the flexible screen 120 is bent and folded along an outer edge of the first roller 130 by taking the axis of the first pivot 113 as the center of circle, and drives the first roller 130 to rotate together.

According to the foldable electronic device of the present invention, the flexible screen is unfolded or folded together with the foldable casing. However, when the flexible screen is folded, creases may be generated. Therefore, the foldable electronic device of the present invention has a roller, and the roller is disposed on a bearing to which the foldable casing is pivoted and is pressed against the flexible screen, and has a radius greater than the flexible radius of the flexible screen, such that the flexible screen is capable of being bent along the outer diameter of the roller and extending and sliding, and thus no crease is generated in the flexible screen and no frictions and damages on the foldable casing occur. Therefore, the present invention solves the problems and applies the flexible display in the foldable electronic device to achieve the efficacy of having a minimal volume when being folded and having a maximal display screen when being unfolded.

1. A foldable electronic device, comprising:
a foldable casing, capable of being unfolded or folded;
a flexible electronic element, disposed in the foldable casing, wherein the flexible electronic element and the foldable casing are unfolded or folded together; and
at least one roller, correspondingly pivoted to a bending position of the foldable casing, wherein the roller has a smooth annular outer edge, the flexible electronic element slides and is bent along the smooth annular outer edge of the roller when being folded.

2. The foldable electronic device according to claim 1, wherein the foldable casing has at least two casing bodies, and the two casing bodies are pivoted to each other, and capable of being unfolded and folded with respect to each other, when the two casing bodies are unfolded with respect to each other, a bearing range is formed thereby, and the flexible electronic element is disposed on the bearing range.

3. The foldable electronic device according to claim 2, wherein the two casing bodies are pivoted to each other through at least one pivot, the roller is pivoted to the pivot, and the smooth annular outer edge of the roller is normally pressed against the flexible electronic element, such that the flexible electronic element slides and is bent along the smooth annular outer edge of the roller when being folded.

4. The foldable electronic device according to claim 1, wherein the foldable casing has three casing bodies, the three casing bodies are pivoted to each other, and capable of being unfolded and folded with respect to each other, when the three casing bodies are unfolded with respect to each other, a bearing range is formed thereby, and the flexible electronic element is disposed on the bearing range.

5. The foldable electronic device according to claim 4, wherein the number of the at least one roller is two, the three casing bodies are pivoted to each other through two pivots, the two rollers are respectively pivoted to the two pivots, and the smooth annular outer edges of the two roller are normally pressed against the flexible electronic element, such that the flexible electronic element slides and is bent along the smooth annular outer edges of the two rollers when being folded.

6. The foldable electronic device according to claim 5, wherein one of the two rollers has an outer diameter greater than an outer diameter of the other one.

7. The foldable electronic device according to claim 1, wherein a roller radius of the roller is greater than a flexible radius of the flexible electronic element.
